(19) United States
(12) Patent Application Publication
(10) Pub. No.: US 2025/0357350 A1
(43) Pub. Date: Nov. 20, 2025

(54) INTERCONNECT STRUCTURE AND METHODS OF FORMING THE SAME

(71) Applicant: TAIWAN SEMICONDUCTOR MANUFACTURING COMPANY, LTD., Hsinchu (TW)

(72) Inventor: Shu-Cheng CHIN, Hsinchu (TW)

(21) Appl. No.: 19/283,276

(22) Filed: Jul. 29, 2025

Related U.S. Application Data
(62) Division of application No. 17/722,302, filed on Apr. 16, 2022.
(60) Provisional application No. 63/298,792, filed on Jan. 12, 2022.

(51) Int. Cl. H01L 23/535; H01L 21/768; H01L 23/532

(52) U.S. Cl. CPC H01L 23/535; H01L 21/76805; H01L 21/76846; H01L 21/76895; H01L 23/53238

(57) ABSTRACT

An interconnect structure and methods of forming the same are described. In some embodiments, the structure includes a first dielectric layer disposed over one or more devices, a first conductive feature disposed in the first dielectric layer, a second conductive feature disposed in the first dielectric layer, an etch stop layer disposed on the first dielectric layer, a second dielectric layer disposed on the etch stop layer, and a third conductive feature disposed in the second dielectric layer and the etch stop layer. The third conductive feature includes a first conductive layer, which includes a two-dimensional material. The structure further includes a fourth conductive feature disposed in the second dielectric layer and the etch stop layer. The third conductive feature and the fourth conductive feature include different number of layers.

### CROSS-REFERENCE TO RELATED APPLICATIONS

This application is a divisional application of U.S. patent application Ser. No. 17/722,302, filed Apr. 16, 2022, which claims priority to U.S. Provisional Application No. 63/298,792, filed on Jan. 12, 2022, the contents of which are hereby incorporated by reference in their entirety.

### BACKGROUND

As the semiconductor industry introduces new generations of integrated circuits (IC) having higher performance and more functionality, the density of the elements forming the ICs increases, while the dimensions, sizes and spacing between components or elements are reduced. In the past, such reductions were limited only by the ability to define the structures photo-lithographically, device geometries having smaller dimensions created new limiting factors. With decreasing semiconductor device dimensions, improved semiconductor devices with improved sheet resistance are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view of one of various stages of manufacturing a semiconductor device structure, in accordance with some embodiments.

FIG. 1B is a cross-sectional side view of the stage of manufacturing the semiconductor device structure taken along line A-A of FIG. 1A, in accordance with some embodiments.

FIG. 2 is a cross-sectional side view of a stage of manufacturing the semiconductor device structure, in accordance with some embodiments.

FIGS. 3A-3H are cross-sectional side views of various stages of manufacturing an interconnect structure, in accordance with some embodiments.

FIGS. 4A-4C are various views of one of various stages of manufacturing the interconnect structure, in accordance with some embodiments.

FIGS. 5A and 5B are cross-sectional side views of a conductive feature, in accordance with alternative embodiments.

FIGS. 6A-6D are cross-sectional side views of various stages of manufacturing a conductive layer, in accordance with some embodiments.

FIGS. 7A-7D are cross-sectional side views of various stages of manufacturing the conductive layer, in accordance with alternative embodiments.

FIG. 8 is a cross-sectional side view of one of various stages of manufacturing the conductive layer, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

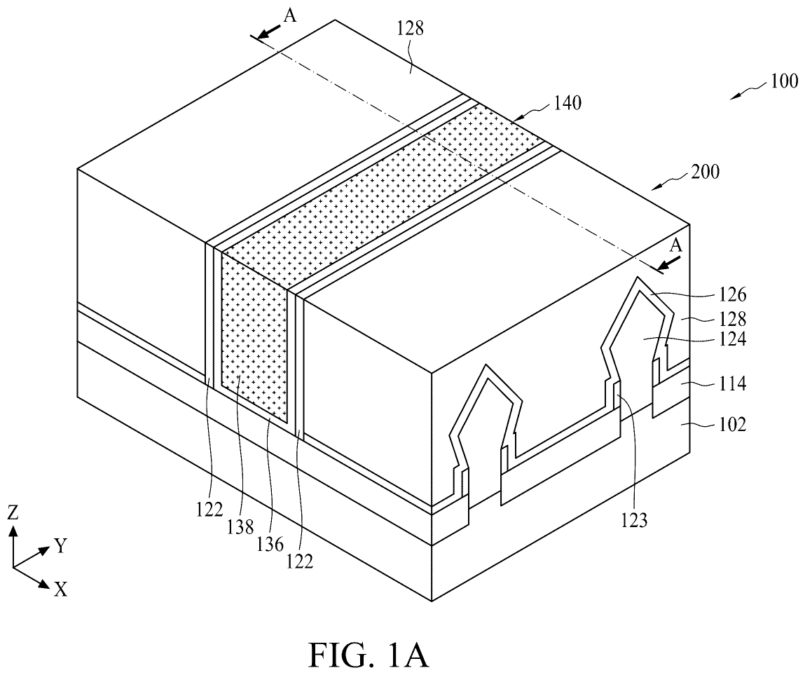

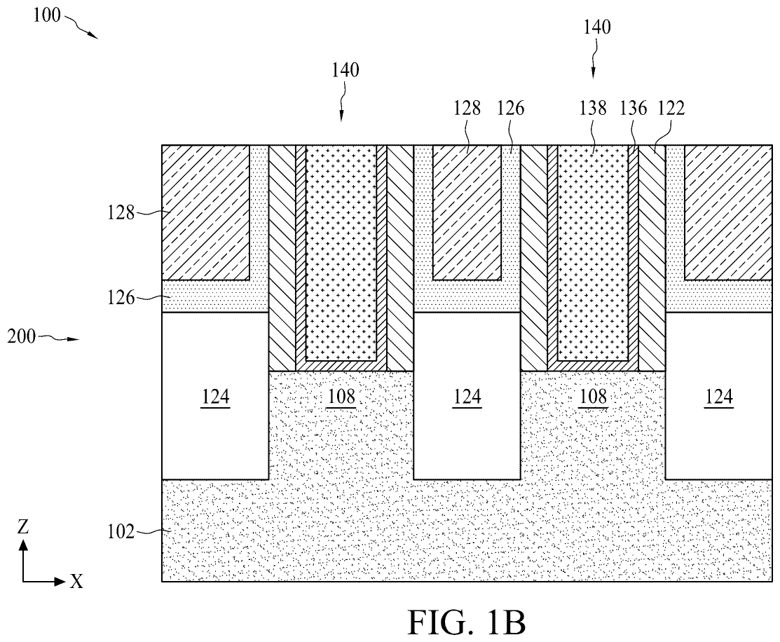

FIGS. 1A and 1B illustrate a stage of manufacturing a semiconductor device structure 100. As shown in FIGS. 1A and 1B, the semiconductor device structure 100 includes a substrate 102 and one or more devices 200 formed on the substrate 102. The substrate 102 may be a semiconductor substrate. In some embodiments, the substrate 102 includes a single crystalline semiconductor layer on at least the surface of the substrate 102. The substrate 102 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), and indium phosphide (InP). For example, the substrate 102 is made of Si. In some embodiments, the substrate 102 is a silicon-on-insulator (SOI) substrate, which includes an insulating layer (not shown) disposed between two silicon layers. In one aspect, the insulating layer is an oxygen-containing material, such as an oxide.

The substrate 102 may include one or more buffer layers (not shown) on the surface of the substrate 102. The buffer layers can serve to gradually change the lattice constant from that of the substrate to that of the source/drain regions. The buffer layers may be formed from epitaxially grown crystalline semiconductor materials such as, but not limited to Si, Ge, germanium tin (GeSn), SiGe, GaAs, InSb, GaP, GaSb, InAlAs, InGaAs, GaSbP, GaAsSb, GaN, GaP, and InP.

The substrate 102 may include various regions that have been suitably doped with impurities (e.g., p-type or n-type impurities). The dopants are, for example phosphorus for an n-type fin field effect transistor (FinFET) and boron for a p-type FinFET.

As described above, the devices 200 may be any suitable devices, such as transistors, diodes, imaging sensors, resistors, capacitors, inductors, memory cells, or a combination thereof. In some embodiments, the devices 200 are transistors, such as planar field effect transistors (FETs), FinFETs, nanostructure transistors, or other suitable transistors. The nanostructure transistors may include nanosheet transistors, nanowire transistors, gate-all-around (GAA) transistors, multi-bridge channel (MBC) transistors, or any transistors having the gate electrode surrounding the channels. An example of the device 200 formed on the substrate 102 is a FinFET, which is shown in FIGS. 1A and 1B. The device 200 includes source/drain (S/D) regions 124 and gate stacks 140 (only one is shown in FIG. 1A). Each gate stack 140 may be disposed between S/D regions 124 serving as source regions and S/D regions 124 serving as drain regions. For example, each gate stack 140 may extend along the Y-axis between one or more S/D regions 124 serving as source regions and one or more S/D regions 124 serving as drain regions. As shown in FIG. 1B, two gate stacks 140 are formed on the substrate 102. In some embodiments, more than two gate stacks 140 are formed on the substrate 102. Channel regions 108 are formed between S/D regions 124 serving as source regions and S/D regions 124 serving as drain regions.

The S/D regions 124 may include a semiconductor material, such as Si or Ge, a III-V compound semiconductor, a II-VI compound semiconductor, or other suitable semiconductor material. Exemplary S/D region 124 may include, but are not limited to, Ge, SiGe, GaAs, AlGaAs, GaAsP, SiP, InAs, AlAs, InP, GaN, InGaAs, InAlAs, GaSb, AIP, GaP, and the like. The S/D regions 124 may include p-type dopants, such as boron; n-type dopants, such as phosphorus or arsenic; and/or other suitable dopants including combinations thereof. The S/D regions 124 may be formed by an epitaxial growth method using CVD, atomic layer deposition (ALD) or molecular beam epitaxy (MBE). The channel regions 108 may include one or more semiconductor materials, such as Si, Ge, GeSn, SiGe, GaAs, InSb, GaP, GaSb, InAlAs, InGaAs, GaSbP, GaAsSb, GaN, GaP, or InP. In some embodiments, the channel regions 108 include the same semiconductor material as the substrate 102. In some embodiments, the devices 200 are FinFETs, and the channel regions 108 are a plurality of fins disposed below the gate stacks 140. In some embodiments, the devices 200 are nanostructure transistors, and the channel regions 108 are surrounded by the gate stacks 140.

As shown in FIGS. 1A and 1B, each gate stack 140 includes a gate electrode layer 138 disposed over the channel region 108 (or surrounding the channel region 108 for nanostructure transistors). The gate electrode layer 138 may be a metal-containing material such as tungsten, cobalt, aluminum, ruthenium, copper, multilayers thereof, or the like, and can be deposited by ALD, plasma enhanced chemical vapor deposition (PECVD), MBD, physical vapor deposition (PVD), or any suitable deposition technique. Each gate stack 140 may further include a gate dielectric layer 136 disposed over the channel region 108. The gate electrode layer 138 may be disposed over the gate dielectric layer 136. In some embodiments, an interfacial layer (not shown) may be disposed between the channel region 108 and the gate dielectric layer 136, and one or more work function layers (not shown) may be formed between the gate dielectric layer 136 and the gate electrode layer 138. The interfacial dielectric layer may include a dielectric material, such as an oxygen-containing material or a nitrogen-containing material, or multilayers thereof, and may be formed by any suitable deposition method, such as CVD, PECVD, or ALD. The gate dielectric layer 136 may include a dielectric material such as an oxygen-containing material or a nitrogen-containing material, a high-k dielectric material having a k value greater than that of silicon dioxide, or multilayers thereof. The gate dielectric layer 136 may be formed by any suitable method, such as CVD, PECVD, or ALD. In some embodiments, the gate dielectric layer 136 may be a conformal layer. The term “conformal” may be used herein for ease of description upon a layer having substantial same thickness over various regions. The one or more work function layers may include aluminum titanium carbide, aluminum titanium oxide, aluminum titanium nitride, or the like.

Gate spacers 122 are formed along sidewalls of the gate stacks 140 (e.g., sidewalls of the gate dielectric layers 136). The gate spacers 122 may include silicon oxycarbide, silicon nitride, silicon oxynitride, silicon carbon nitride, the like, multi-layers thereof, or a combination thereof, and may be deposited by CVD, ALD, or other suitable deposition technique.

As shown in FIG. 1A, fin sidewall spacers 123 may be disposed on opposite sides of each S/D region 124, and the fin sidewall spacers 123 may include the same material as the gate spacers 122. Portions of the gate stacks 140, the gate spacers 122, and the fin sidewall spacers 123 may be disposed on isolation regions 114. The isolation regions 114 are disposed on the substrate 102. The isolation regions 114 may include an insulating material such as an oxygen-containing material, a nitrogen-containing material, or a combination thereof. In some embodiments, the isolation regions 114 are shallow trench isolation (STI). The insulating material may be formed by a high-density plasma chemical vapor deposition (HDP-CVD), a flowable chemical vapor deposition (FCVD), or other suitable deposition process. In one aspect, the isolation regions 114 includes silicon oxide that is formed by a FCVD process.

As shown in FIGS. 1A and 1B, a contact etch stop layer (CESL) 126 is formed on the S/D regions 124 and the isolation region 114, and an interlayer dielectric (ILD) layer 128 is formed on the CESL 126. The CESL 126 can provide a mechanism to stop an etch process when forming openings in the ILD layer 128. The CESL 126 may be conformally deposited on surfaces of the S/D regions 124 and the isolation regions 114. The CESL 126 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be deposited by CVD, PECVD, ALD, or any suitable deposition technique. The ILD layer 128 may include an oxide formed by tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), organosilicate glass (OSG), SiOC, and/or any suitable low-k dielectric materials (e.g., a material having a dielectric constant lower than that of silicon dioxide), and may be deposited by spin-on, CVD, FCVD, PECVD, PVD, or any suitable deposition technique.

A conductive contact (not shown) may be disposed in the ILD layer 128 and over the S/D region 124. The conductive contact may be electrically conductive and include a material having one or more of Ru, Mo, Co, Ni. W, Ti, Ta, Cu, Al, TiN or TaN, and the conductive contact may be formed by any suitable method, such as electro-chemical plating (ECP), or PVD. A silicide layer (not shown) may be disposed between the conductive contact and the S/D region 124.

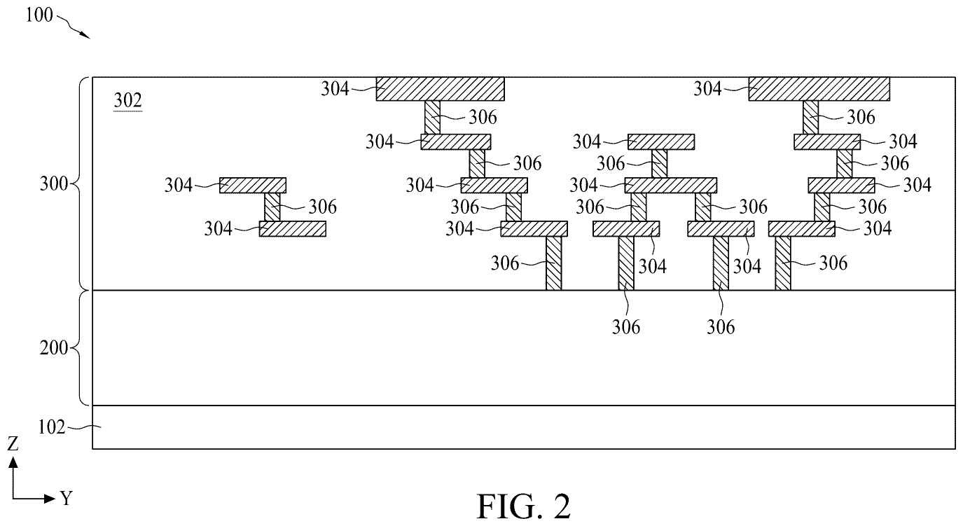

The semiconductor device structure 100 may further includes an interconnection structure 300 disposed over the devices 200 and the substrate 102, as shown in FIG. 2. The interconnection structure 300 includes various conductive features, such as a first plurality of conductive features 304 and second plurality of conductive features 306, and an intermetal dielectric (IMD) layer 302 to separate and isolate various conductive features 304, 306. Etch stop layers may be omitted for clarity. In some embodiments, the first plurality of conductive features 304 are conductive lines and the second plurality of conductive features 306 are conductive vias. The interconnection structure 300 includes multiple levels of the conductive features 304, and the conductive features 304 are arranged in each level to provide electrical paths to various devices 200 disposed below. The conductive features 306 provide vertical electrical routing from the devices 200 to the conductive features 304 and between conductive features 304. For example, the bottom-most conductive features 306 of the interconnection structure 300 may be electrically connected to the conductive contacts disposed over the S/D regions 124 (FIG. 1B) and the gate electrode layer 138 (FIG. 1B). The conductive features 304 and conductive features 306 may be made from one or more electrically conductive materials, such as metal, metal alloy, metal nitride, or silicide. For example, the conductive features 304 and the conductive features 306 are made of copper, aluminum, rhodium, ruthenium, iridium, aluminum copper alloy, titanium, titanium nitride, tantalum, tantalum nitride, titanium silicon nitride, zirconium, gold, silver, cobalt, nickel, tungsten, tungsten nitride, tungsten silicon nitride, platinum, chromium, molybdenum, hafnium, other suitable conductive material, or a combination thereof. In some embodiments, the conductive features 304, 306 may include a two-dimensional material.

The IMD layer 302 includes one or more dielectric materials to provide isolation functions to various conductive features 304, 306. The IMD layer 302 may include multiple dielectric layers embedding multiple levels of conductive features 304, 306. The IMD layer 302 is made from a dielectric material, such as SiOₓ, SiOₓC_{y}H_{z}, or SiOₓC_{y}, where x, y and z are integers or non-integers. In some embodiments, the IMD layer 302 includes a dielectric material having a k value ranging from about 1 to about 5.

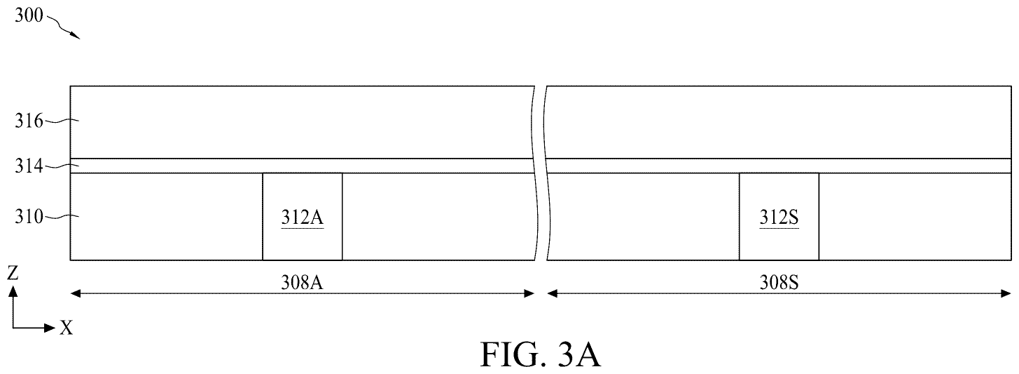

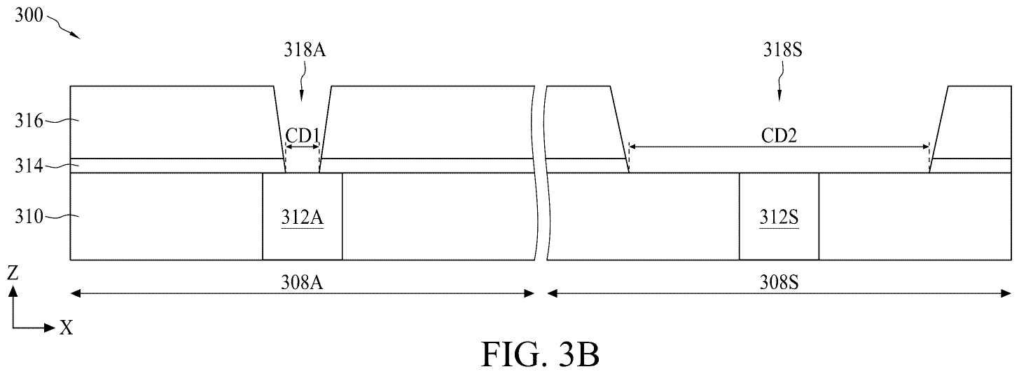

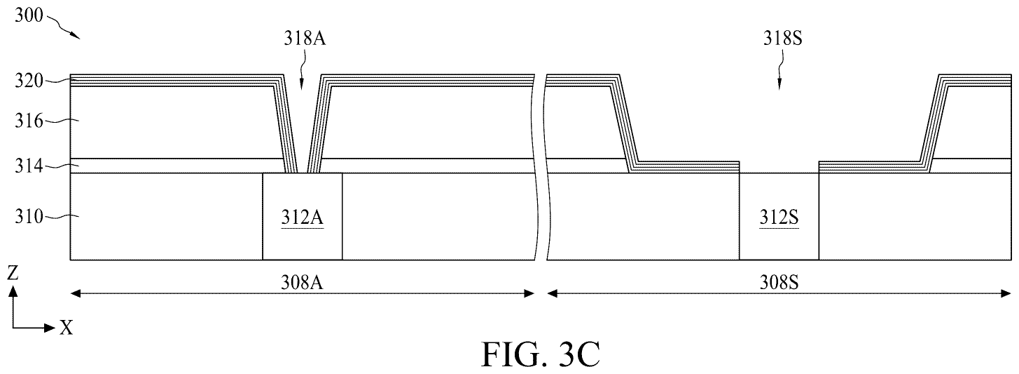

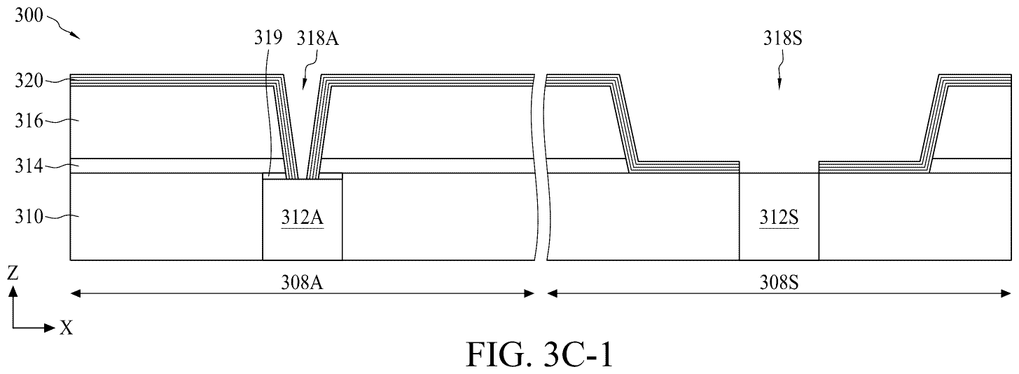

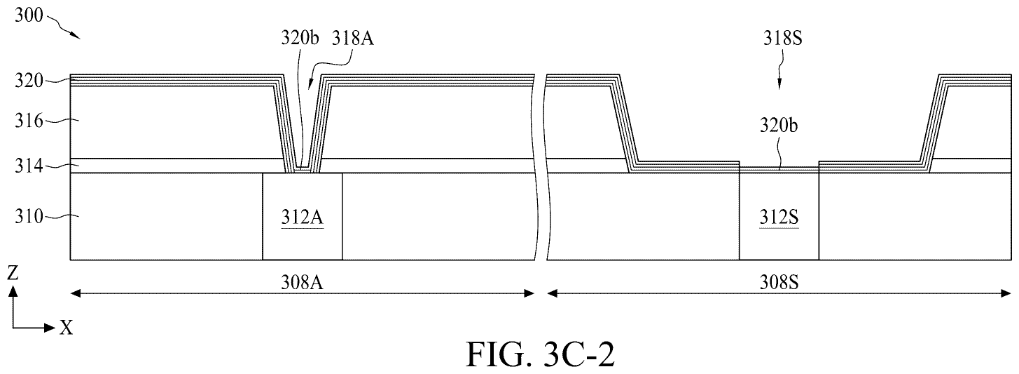

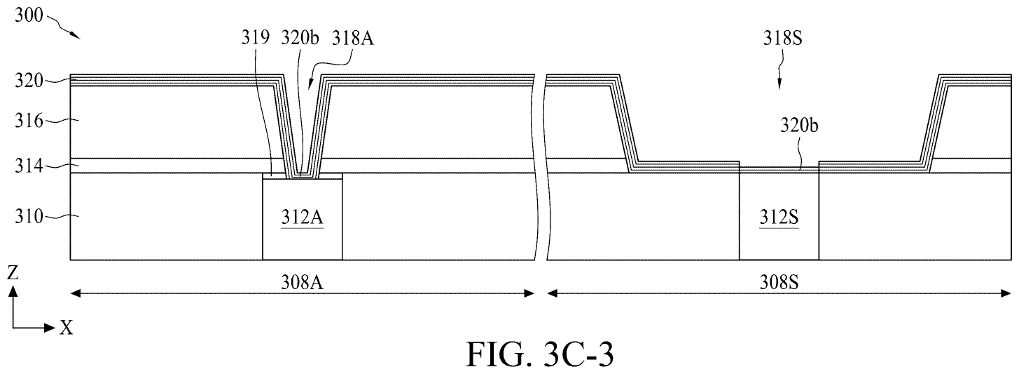

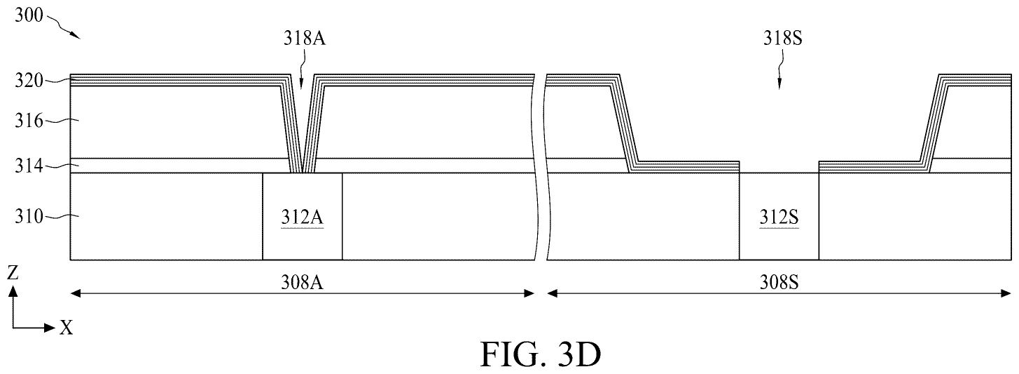

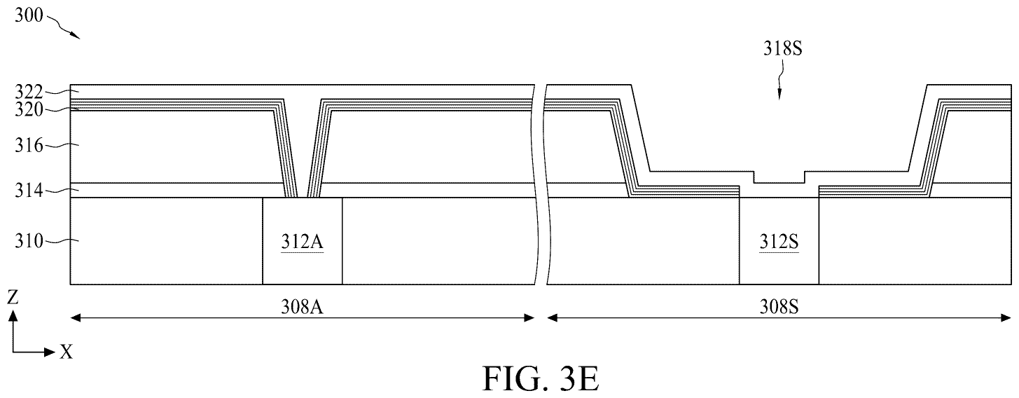

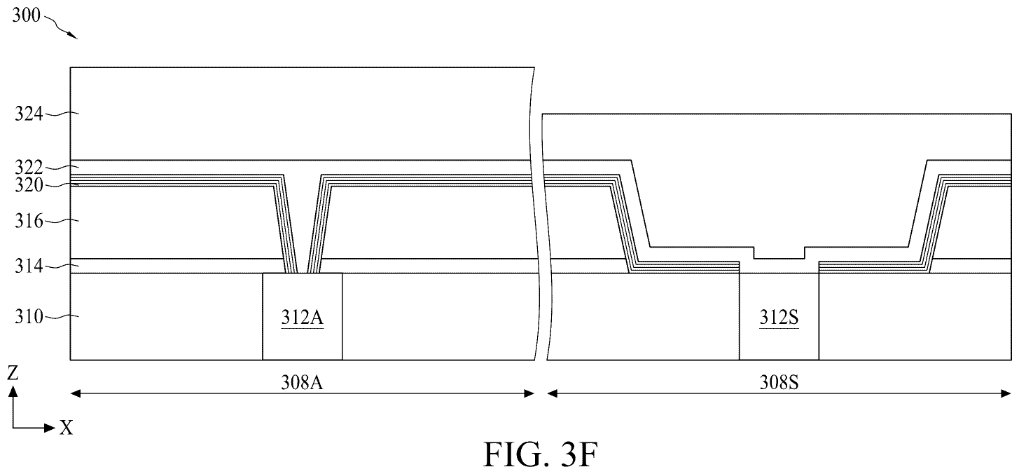

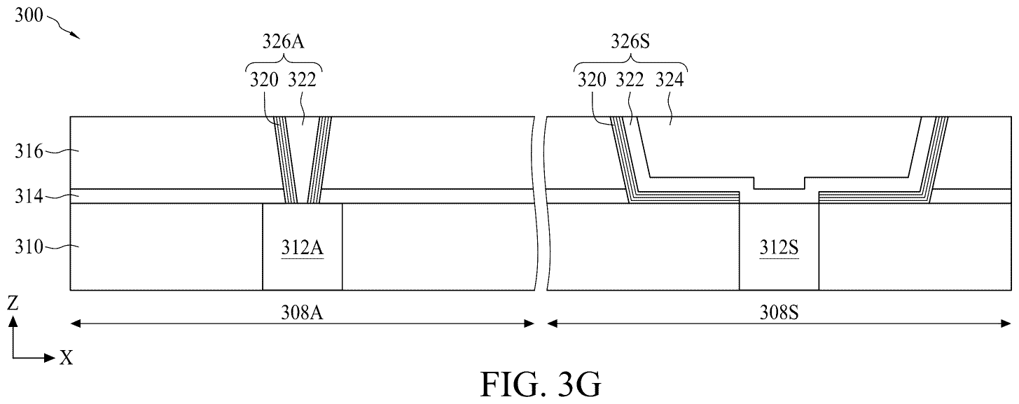

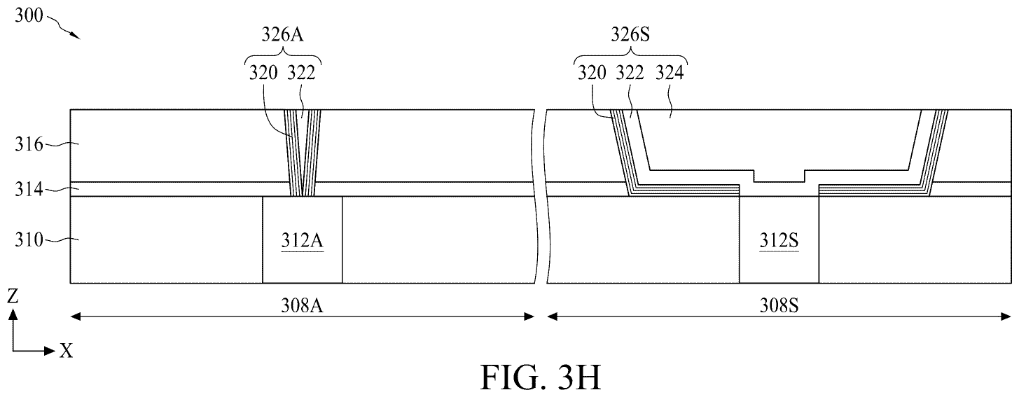

FIGS. 3A-3H are cross-sectional side views of various stages of manufacturing the interconnect structure 300, in accordance with some embodiments. As shown in FIG. 3A, the interconnect structure 300 includes a dielectric layer 310, which may be an ILD layer or an IMD layer. For example, the dielectric layer 310 may be the ILD layer 128 (FIGS. 1A and 1B) or the IMD layer 302 (FIG. 2). The dielectric layer 310 may include the same material as the ILD layer 128 or the IMD layer 302. In some embodiments, the dielectric layer 310 includes a low-k dielectric material, SiO₂, SiOC, SiON, SiOC, SiOCN, or other suitable dielectric material. In some embodiments, the low-k dielectric material includes SiOCH. The dielectric layer 310 may be formed by CVD, FCVD, ALD, spin coating, or other suitable process. The interconnect structure 300 includes an active region 308A and a sealing ring region 308S, and the regions 308A, 308S may be located next to each other or located spaced apart from each other.

One or more conductive features 312A, 312S are disposed in the dielectric layer 310. The one or more conductive features 312A (only one is shown) are disposed in the dielectric layer 310 in the active region 308A, and the one or more conductive features 312S (only one is shown) are disposed in the sealing ring region 308S. The conductive features 312A, 312S each includes an electrically conductive material, such as Cu, Co, Ru, Mo, Cr, W, Mn, Rh, Ir, Ni, Pd, Pt, Ag, Au, Al, Ta, TaN, TiN, alloys thereof, or other suitable material. The conductive features 312A, 312S are formed by any suitable process, such as ECP, electroless deposition (ELD), PVD, or CVD. In some embodiments, the conductive features 312A, 312S may be the conductive features 306 shown in FIG. 2. For example, the conductive features 312A, 312S may be conductive vias having the same or different dimensions. In some embodiments, the conductive feature 312S has larger dimensions than the conductive feature 312A. In some embodiments, a barrier layer (not shown) may be formed between the dielectric layer 310 and the conductive features 312A, 312S, and a liner (not shown) may be formed between the barrier layer and the conductive features 312A, 312S. The barrier layer and the liner may be formed by any suitable process, such as CVD, PECVD, or ALD.

An etch stop layer 314 is formed on the dielectric layer 310 and the conductive features 312A, 312S in the active region 308A and the sealing ring region 308S. The etch stop layer 314 may include a nitrogen-containing material or an oxygen-containing material. For example, the etch stop layer 314 may be a nitride or an oxide, such as silicon nitride, a metal nitride, silicon oxide, or a metal oxide. In some embodiments, the etch stop layer 314 includes the same material as the CESL 126 (FIG. 1A). The etch stop layer 314 may be formed by any suitable process, such as CVD, PECVD, ALD, PEALD, or any suitable process. In some embodiments, the etch stop layer 314 is a conformal layer formed by ALD. A dielectric layer 316 is formed on the etch stop layer 314 in the active region 308A and the sealing ring region 308S. The dielectric layer 316 may include the same material as the dielectric layer 310 and may be formed by the same process as the dielectric layer 310.

As shown in FIG. 3B, openings 318A, 318S are formed in the dielectric layer 316 and the etch stop layer 314 in the active region 308A and the sealing ring region 308S, respectively. Each opening 318A, 318S may be formed by one or more etch processes. The opening 318S has larger dimensions than the opening 318A. For example, the opening 318A has a bottom critical dimension CD1 less than about 10 nm, such as from about 6 nm to about 10 nm. The bottom critical dimension CD1 may be the smallest dimension of the opening 318A along the x-axis, as shown in FIG. 3B. The critical dimension of the opening 318A along the x-axis may decrease gradually from the top to the bottom of the opening 318A. In some embodiments, the critical dimension of the opening 318A along the x-axis may be substantially constant and is the same as the bottom critical dimension CD1. The opening 318S has a bottom critical dimension CD2 greater than about 10 nm, such as from about 20 nm to about 200 nm. The bottom critical dimension CD2 may be the smallest dimension of the opening 318S along the x-axis, as shown in FIG. 3B. The critical dimension of the opening 318S along the x-axis may decrease gradually from the top to the bottom of the opening 318S. In some embodiments, the critical dimension of the opening 318S along the x-axis may be substantially constant and is the same as the bottom critical dimension CD2. In some embodiments, as shown in FIG. 3B, the critical dimensions CD1, CD2 are along the x-axis. The dimensions of the openings 318A, 318S along the y-axis may be substantially greater than the bottom critical dimensions CD1, CD2, respectively. In some embodiments, the bottom critical dimensions CD1, CD2 are along the y-axis, and the dimensions of the openings 318A, 318S along the x-axis may be substantially greater than the bottom critical dimensions CD1, CD2, respectively. In some embodiments, the openings 318A, 318S are trenches.

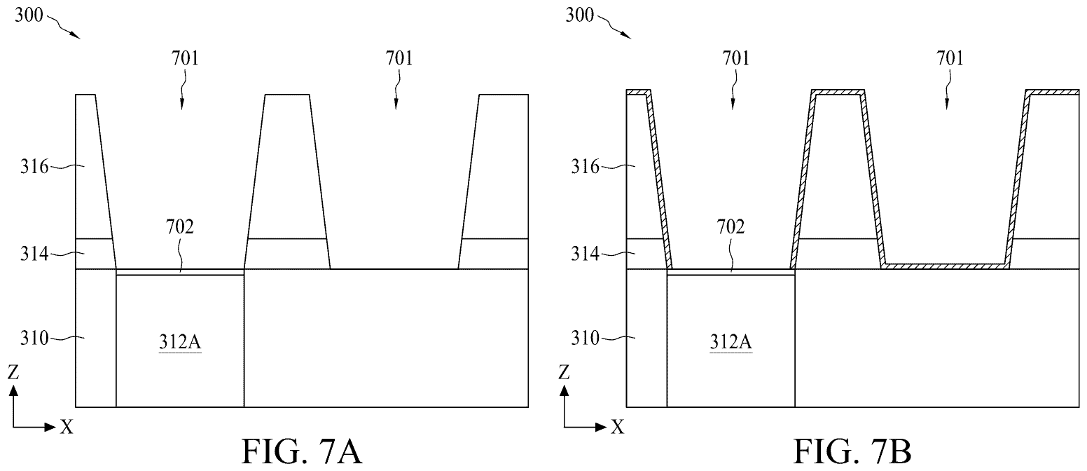

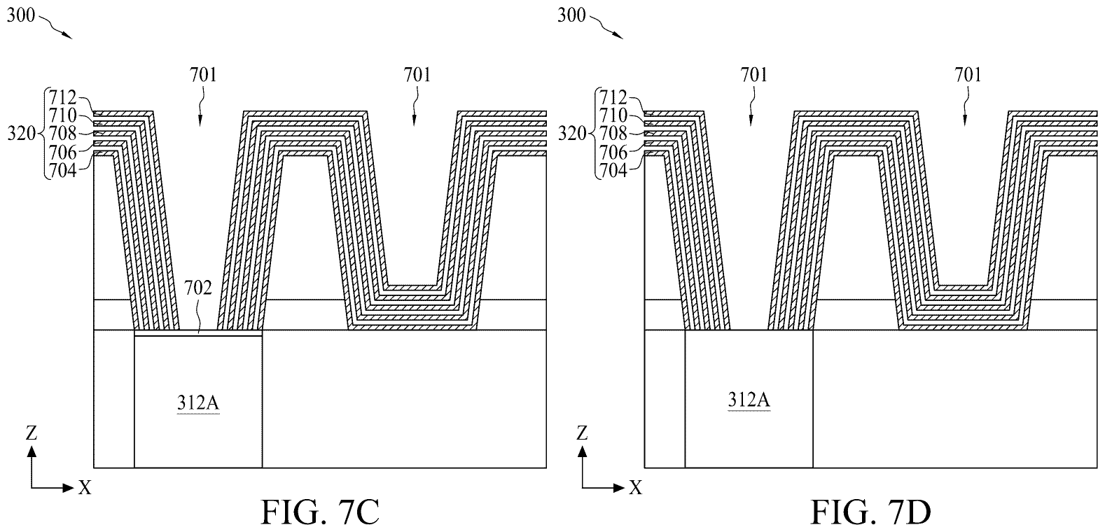

As shown in FIG. 3C, a first conductive layer 320 is formed on the dielectric layer 316 and in the openings 318A, 318S. The first conductive layer 320 is formed on the sidewalls of the dielectric layer 316 and the etch stop layer 314 in the openings 318A, 318S. The first conductive layer 320 includes 3 to 6 two-dimensional (2D) material layers. The term “2D material” used in this disclosure refers to single layer material or monolayer-type material that is atomically thin crystalline solid having intralayer covalent bonding and interlayer van der Waals bonding. Examples of a 2D material may include graphene, hexagonal boron nitride (h-BN), or transition metal dichalcogenides (MX₂), where M is a transition metal element and X is a chalcogenide element. Some exemplary MX₂ materials may include, but are not limited to CrSe₂, CrTe₂, VS₂, VSe₂, VTe₂, TaS₂, TaSe₂, TaTe₂, MoS₂, MoSe₂, MoTe₂, NbS₂, NbSe₂, NbTe₂, WS₂, WSe₂, WTe₂, TiS₂, TiSe₂, TiTe₂, or any combination thereof. In some embodiments, the 2D material includes S, Se, Te, FeS, FeSe, BP, Mo₂C, Si, Ge, Sn, other suitable 2D material, or combinations thereof. In some embodiments, the first conductive layer 320 is selectively formed on the dielectric materials of the dielectric layer 316 and the etch stop layer 314 and is not formed on the conductive features 312A, 312S. For example, the first conductive layer 320 may be graphene layers formed using a water-assisted CVD process. The water-assisted CVD process does not use metal catalysts. Thus, as a result, the first conductive layer 320 is not formed on the metallic surfaces of the conductive features 312A, 312S. In another example, as described in detail in FIGS. 7A-7D, a blocking layer 702 (FIG. 7A) is selectively formed on the conductive features 312A, 312S and blocks the formation of the 2D material of the first conductive layer 320 on the conductive features 312A, 312S.

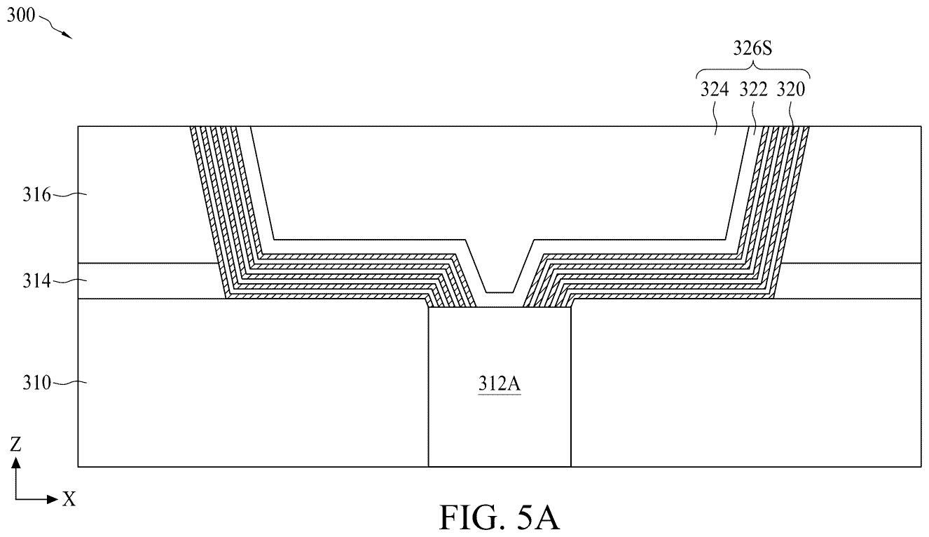

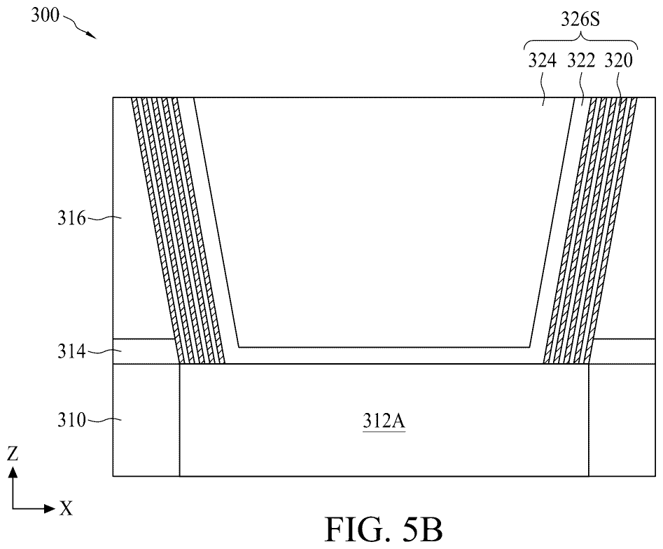

In some embodiments, as shown in FIG. 3C-1, each of the top surface of the conductive features 312A, 312S includes an oxide layer 319. The oxide layer 319 may be formed as a result of oxidation of the conductive features 312A, 312S during processes. The oxide layer 319 may be a metal oxide layer that includes the metal of the conductive features 312A, 312S. The oxide layer 319 may be also formed on the conductive feature 312A shown in FIGS. 5A, 5B, 6A-6D, and 7A-7D, in some embodiments. In some embodiments, similar to the embodiment shown in FIG. 3C, the first conductive layer 320 is not formed on the oxide layer 319. For example, the 2D material of the first conductive layer 320 is formed on the silicon-based oxide and/or nitride of the dielectric layer 316 and the etch stop layer 314 but is not formed on the metal oxide material of the oxide layer 319. In another example, the blocking layer 702 (FIG. 7A) is selectively formed on the oxide layers 319 to block the formation of the 2D material of the first conductive layer 320 on the conductive features 312A, 312S. In some embodiments, before forming the first conductive layer 320, the exposed portion of the oxide layer 319 may be removed.

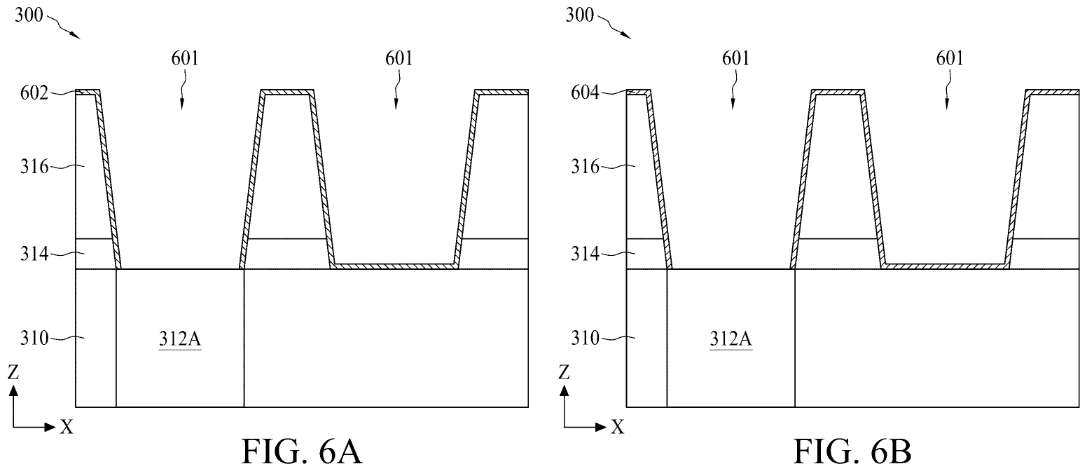

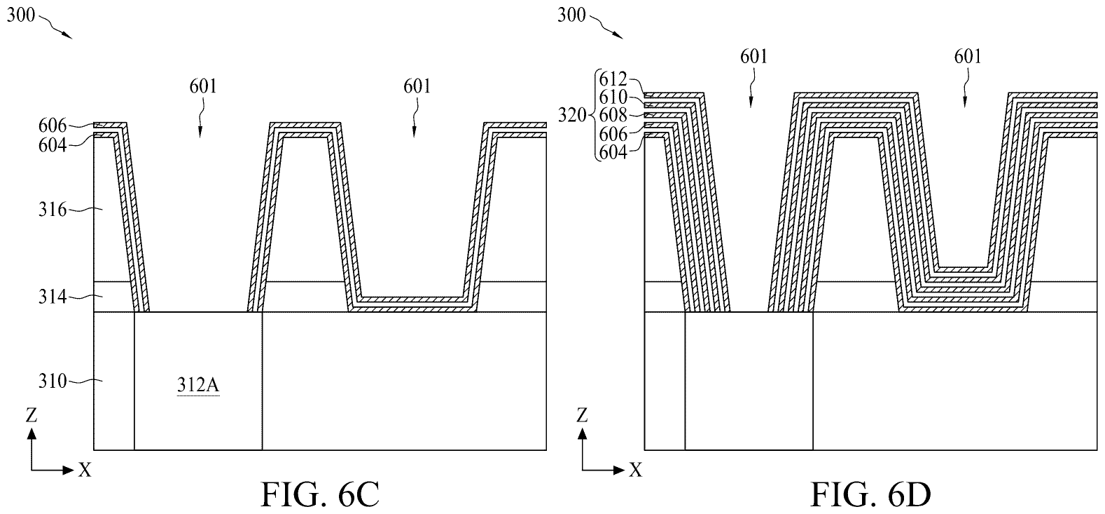

As shown in FIG. 3C-2, in some embodiments, a portion 320b of the first conductive layer 320 is formed on the conductive features 312A, 312S. The portion 320b may have a thickness less than half of the thickness of the portion of the first conductive layer 320 formed on the dielectric layer 316. The growth rate of the portion 320b is substantially slower than the growth rate of the portions of the first conductive layer 320 formed on the dielectric layer 316 and on the etch stop layer 314. As a result, the thickness of the portion 320b is substantially less than a thickness of the portion of the first conductive layer 320 formed on the dielectric layer 316 and the etch stop layer 314. The portion 320b may be also formed on the conductive feature 312A shown in FIGS. 5A, 5B, and 6A-6D, in some embodiments. As shown in FIG. 3C-3, in some embodiments, the portion 320b of the first conductive layer 320 is formed on the oxide layer 319. In some embodiments, before forming the first conductive layer 320, the exposed portion of the oxide layer 319 may be removed.

The first conductive layer 320 has the lowest electrical resistivity when the number of the 2D material layers ranges from 3 to 6. The electrical resistivity of the first conductive layer 320 increases if the number of the 2D material layers is less than 3 or greater than 6. In some embodiments, the 2D material layers may be doped with a dopant to further reduce the electrical resistivity. For example, the 3 to 6 2D material layers may be doped with Nb, Cu, Mn, or other suitable dopant.

In some embodiments, the first conductive layer 320 is formed by forming a first 2D material layer on the dielectric layer 316 and on the sidewalls of the dielectric layer 316 and the etch stop layer 314 in the openings 318A, 318S. Then, a second 2D material layer is formed on the first 2D material layer, followed by a third 2D material layer being formed on the second 2D material layer. In some embodiments, 3 to 6 2D material layers are formed on the dielectric layer 316 and on the sidewalls of the dielectric layer 316 and the etch stop layer 314 in the openings 318A, 318S. Thus, the 2D material layers are formed in a direction substantially perpendicular to the surface of the dielectric layer 316. In other words, the 3 to 6 2D material layers are stacked in a direction substantially perpendicular to the surface of the dielectric layer 316 the 2D material layers formed thereon. Various methods for forming the first conductive layer 320 are described in FIGS. 6A to 6D and FIGS. 7A to 7D.

In some embodiments, the first conductive layer 320, which includes 3 to 6 2D material layers, has a thickness ranging from about 2 nm to about 9 nm. Even though in some embodiments the first conductive layer 320 may be selectively formed on the dielectric materials, at least a portion of the conductive feature 312A may be covered by the first conductive layer 320 due to the small bottom critical dimension CD1 (FIG. 3B) of the opening 318A. As described above, the bottom critical dimension CD1 (FIG. 3B) of the opening 318A may range from about 6 nm to about 10 nm. Thus, in some embodiments, as shown in FIG. 3C, the bottom critical dimension CD1 (FIG. 3B) is greater than twice the thickness of the first conductive layer 320, and a gap is formed at the bottom of the opening 318A between the portions of the first conductive layer 320. A portion of the conductive feature 312A may be exposed in the gap. In some embodiments, as shown in FIG. 3D, the bottom critical dimension CD1 (FIG. 3B) is less than twice the thickness of the first conductive layer 320, and the portions of the first conductive layer 320 formed on the sidewalls of the etch stop layer 314 are merged. In other words, the bottom of the opening 318A may be covered by the first conductive layer 320, and the first conductive layer 320 is in contact with the conductive feature 312A. The first conductive layer 320 may not be formed on the conductive feature 312S or may cover edge portions of the conductive feature 312S. At least a portion of the conductive feature 312S is exposed in the opening 318S.

As shown in FIG. 3E, a second conductive layer 322 is formed on the first conductive layer 320. The second conductive layer 322 fills the opening 318A but not the opening 318S due to the different in size of the openings 318A, 318S. The second conductive layer 322 fills a space between portions of the first conductive layer 320 in the opening 318A. In the embodiment where a portion of the conductive feature 312A is exposed, the second conductive layer 322 is in contact with the exposed portion of the conductive feature 312A. The second conductive layer 322 includes a metal, such as Ru, Mo, Rh, or Ir, that has lower electrical resistivity with a dimension less than about 6 nm compared to other metals such as Cu or Co. For example, after forming the first conductive layer 320 in the opening 318A, the bottom critical dimension CD1 (FIG. 3B) of the opening 318A along the x-axis is less than about 6 nm, which means a bottom of the second conductive layer 322 disposed in the opening 318A has a dimension along the x-axis less than about 6 nm. By using Ru, Mo, Rh, or Ir as the second conductive layer 322, electrical resistivity of the second conductive layer 322 is reduced compared to using Cu or Co as the second conductive layer 322.

The second conductive layer 322 is formed by an ALD process in order to improve the gap filling of the opening 318A. As a result, the second conductive layer 322 may be a conformal layer in the opening 318S, as shown in FIG. 3E. The portions of the second conductive layer 322 formed on the portions of the first conductive layer 320 formed along the sidewall defining the opening 318S are conformal. In addition, a portion of the second conductive layer 322 may be conformally formed on the exposed portion of the conductive feature 312S in the sealing ring region 308S. The conformal portion of the second conductive layer 322 formed in the opening 318S may have a thickness ranging from about 1 nm to about 3 nm. In some embodiments, the second conductive layer 322 may be in contact with the conductive features 312A, 322S, as shown in FIG. 3E. In some embodiments, the second conductive layer 322 may be in contact with the portion 320b (FIG. 3C-2) of the first conductive layer 320. In some embodiments, the second conductive layer 322 may be in contact with the oxide layer 319 (FIG. 3C-1).

As shown in FIG. 3F, a third conductive layer 324 is formed on the second conductive layer 322. The third conductive layer 324 fills the opening 318S. The third conductive layer 324 includes a metal, such as Cu, that has lower electrical resistivity with a dimension greater than about 6 nm compared to other metals, such as Ru, Mo, Rh, or Ir. For example, after forming the second conductive layer 322 in the opening 318S, the bottom critical dimension CD1 (FIG. 3B) of the opening 318A along the x-axis is greater than about 10 nm, which means a bottom of the third conductive layer 324 disposed in the opening 318S has a dimension along the x-axis greater than about 6 nm (the first and second conductive layers 320, 322 may take up a portion of the bottom critical dimension CD2). By using Cu as the third conductive layer 324, electrical resistivity of the third conductive layer 324 is reduced compared to using Ru, Mo, Rh, or Ir as the third conductive layer 324. The third conductive layer 324 may be formed by PVD or ECP, which is different from the ALD process that forms the second conductive layer 322.

As shown in FIG. 3G, portions of the first conductive layer 320, the second conductive layer 322, and the third conductive layer 324 disposed on the dielectric layer 316 are removed. The removal of the portions of the layers may be performed by a planarization process, such as a chemical-mechanical polish (CMP) process. The portions of the first conductive layer 320 and the second conductive layer 322 formed in the opening 318A may be a conductive feature 326A, and the portions of the first conductive layer 320, the second conductive layer 322, and the third conductive layer 324 formed in the opening 318S may be a conductive feature 326S. The conductive feature 326A has a first bottom width along the x-axis, which may be the same as the bottom critical dimension CD1. The conductive feature 326S has a second bottom width along the x-axis, which may be the same as the bottom critical dimension CD2. The second width is substantially greater than the first width. The conductive features 326A, 326S may be the conductive features 304 shown in FIG. 2. As shown in FIG. 3G, the conductive feature 326A has the bottom width less than about 10 nm and includes the first conductive layer 320 and the second conductive layer 322. The contact resistance and the sheet resistance of the conductive feature 326A are lower than those of the conventional conductive feature that includes Cu and a barrier layer. As described above, Cu has higher electrical resistivity compared to the materials of the second conductive layer 322 when a dimension is less than about 6 nm. The conductive feature 326S has the bottom width greater than about 10 nm, such as from about 20 nm to about 200 nm, and includes the first conductive layer 320, the second conductive layer 322, and the third conductive layer 324. The contact resistance and the sheet resistance of the conductive feature 326S are lower than those of the conventional conductive feature that includes Cu and a barrier layer. The barrier layer of the conventional conductive feature may be TiN or TaN, which has higher electrical resistivity compared to the materials of the first conductive layer 320, such as 3 to 6 layers of a 2D material. Thus, two conductive features 326A, 326S disposed in the same dielectric layer 316 have different number of materials in order to reduce contact resistance and sheet resistance of the conductive features 326A, 326S. For example, the conductive feature 326A includes a 2D material and a metal, and the conductive feature 326S includes the 2D material, the metal, and an additional metal different from the metal. If the third conductive layer 324 of the conductive feature 326S is made of the same material as the second conductive layer 322, the contact resistance and the sheet resistance of the conductive feature 326S are increased because the electrical resistivity of the third conductive layer 324 is substantially lower than that of the second conductive layer 322 when a dimension is greater than about 6 nm. In some embodiments, the conductive feature 326S is disposed in the active region 308A. In other words, two conductive features 326A, 326S having different sizes and materials are disposed in the active region 308A.

FIG. 3H shows the conductive feature 326A having the first conductive layer 320 formed between the conductive feature 312A and the second conductive layer 322. As described in FIG. 3D, the portions of the first conductive layer 320 formed on the sidewalls of the etch stop layer 314 may be merged and may cover the conductive feature 312A. Thus, the second conductive layer 322 is not in direct contact with the conductive feature 312A, and is electrically connected to the conductive feature 312A via the first conductive layer 320.

As described above, the first conductive layer 320 includes 3 to 6 2D material layers formed in a direction substantially perpendicular to the sidewalls of the dielectric layer 316. In some embodiments, the sidewalls of the dielectric layer 316 may be substantially perpendicular to the top surface of the conductive feature 312A. During operation, an electrical current may flow from the conductive feature 326A to the conductive feature 312A in a direction substantially perpendicular to the top surface of the conductive feature 312A, and electrons are flowing from the conductive feature 312A to the conductive feature 326A in a direction substantially perpendicular to the top surface of the conductive feature 312A. Thus, the 3 to 6 2D material layers are formed in a direction substantially parallel to the direction of the electron flow, and electrons are flowing between adjacent 2D material layers. As a result, contact resistance is reduced compared to a conductive feature that includes a plurality of 2D material layers formed in a direction substantially perpendicular to the top surface of the conductive feature 312A, in which the electrons are flowing through the 2D material layers.

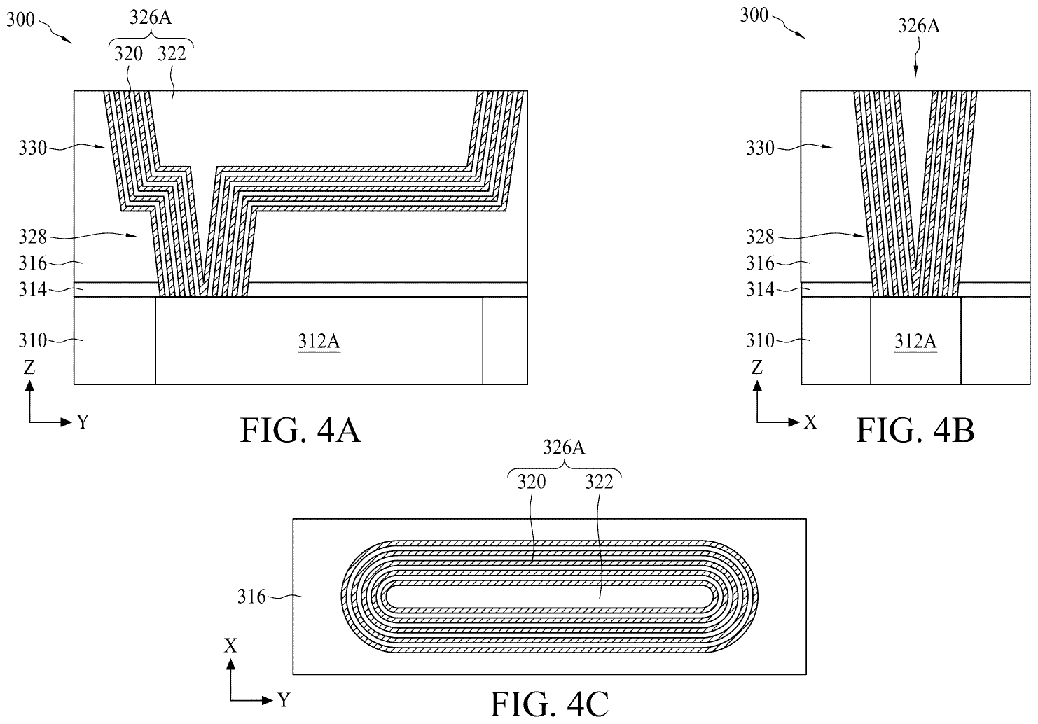

FIGS. 4A-4C are various views of one of various stages of manufacturing the interconnect structure 300, in accordance with some embodiments. As shown in FIG. 4A, the conductive feature 326A may be formed by a dual-damascene process, and the conductive feature 326A includes a via portion 328 and a line portion 330. Each of the via portion 328 and the line portion 330 includes the first conductive layer 320 and the second conductive layer 322. The conductive feature 326A shown in FIG. 3G may be the line portion 330. As shown in FIG. 4B, due to the small dimension in the x-axis, the conductive feature 326A includes the second conductive layer 322, which has a lower electrical resistivity compared to the third conductive layer 324 (FIG. 3H), and does not include the third conductive layer 324. FIG. 4C is a top view of the conductive feature 326A, which includes the second conductive layer 322 surrounded by the first conductive layer 320.

FIGS. 5A and 5B are cross-sectional side views of the conductive feature 326S, in accordance with alternative embodiments. As shown in FIG. 5A, in some embodiments, the conductive feature 312A has a thickness in the z-axis less than a thickness of the dielectric layer 310 due to the dishing effect from a CMP process, and each 2D material layer of the first conductive layer 320 may include a slant portion disposed on the conductive feature 312A. Each 2D material layer may include a horizontal portion disposed over the dielectric layer 310 and is connected to the slant portion. The horizontal portion and the slant portion may form an obtuse angle. The first conductive layer 320 may be formed on portions of the conductive feature 312A, and the second conductive layer 322 are formed on the remaining portion of the conductive feature 312A.

As shown in FIG. 5B, the conductive feature 312A may have a width in the x-axis substantially the same or greater than a width of the conductive feature 326S. As a result, there are no horizontal portions of the first conductive layer 320 formed on the conductive feature 312A.

FIGS. 6A-6D are cross-sectional side views of various stages of manufacturing the first conductive layer 320, in accordance with some embodiments. As shown in FIG. 6A, a first layer 602 is selectively formed on the dielectric surfaces of the dielectric layer 316 and the etch stop layer 314. The first layer 602 may be a transition metal oxide and may be formed by an ALD process. As shown in FIG. 6A, two openings 601 are formed in the dielectric layer 316 and the etch stop layer 314. In some embodiments, the openings 601 are trenches. In some embodiments, the openings 601 includes a via and a trench formed over the via for dual-damascene process. The conductive feature 312A is exposed in one of the two openings 601. A conductive feature (not shown) may be exposed in the other opening 601 of the two openings 601 at a location along the y-axis not shown in FIG. 6A. In some embodiments, no conductive feature is exposed in the other opening 601 of the two openings 601. The first layer 602 is not formed on the metallic surface of the conductive feature 312A.

Next, as shown in FIG. 6B, a sulfurization process is performed on the first layer 602 to form a second layer 604. In some embodiments, the second layer 604 includes a transition metal sulfide, which may be a 2D material. Thus, the second layer 604 may be a 2D material layer. The second layer 604 may be formed by an ALD process, and the formation of the layers 602, 604 described in FIGS. 6A and 6B may be a cycle of the ALD process.

Next, as shown in FIG. 6C, a third layer 606 is formed on the second layer 604. The third layer 606 may be a 2D material layer, such as a layer includes a transition metal sulfide. The third layer 606 may include the same material as the second layer 604 and may be formed by the same process as the second layer 604. The formation of the third layer 606 may be self-limited since the third layer 606 is selectively formed on the second layer 604. Additional layers 608, 610, 612 may be formed on the third layer 606, as shown in FIG. 6D. Each layer 608, 610, 612 may include the same material as the second layer 604 and may be formed by the same process as the second layer 604. The layers 604, 606, 608, 610, 612 may together form the first conductive layer 320. Although 5 layers are shown in FIG. 6D, the number of layers is not limited to 5. As described above, the first conductive layer 320 may include 3 to 6 2D material layers. Subsequent processes such as the processes described in FIGS. 3E to 3H may be performed after the formation of the first conductive layer 320 to fill the openings 601.

FIGS. 7A-7D are cross-sectional side views of various stages of manufacturing the first conductive layer 320, in accordance with alternative embodiments. As shown in FIG. 7A, openings 701 are formed in the dielectric layer 316 and the etch stop layer 314, and a blocking layer 702 is selectively formed on the metallic surface of the conductive feature 312A. In some embodiments, the openings 701 are trenches. In some embodiments, the openings 701 includes a via and a trench formed over the via for dual-damascene process. The blocking layer 702 may include self-assembled monolayers (SAM) having a head group and a tail group. The head group is selectively attached to the conductive feature 312A, while the tail group prevents a layer from forming thereon. As shown in FIG. 7B, a first layer 704 is formed on the dielectric layer 316 and the etch stop layer 314. The blocking layer 702 blocks the first layer 704 from forming thereon. Without the blocking layer 702, the first layer 704 may be formed on the conductive feature 312A. In some embodiments, the first layer 704 is a 2D material layer, such as a graphene layer. In some embodiments, the graphene layer may be selectively formed on the dielectric materials of the dielectric layer 316 and the etch stop layer 314, without the need of the blocking layer 702.

Next, additional layers 706, 708, 710, 712 may be formed on the first layer 704, as shown in FIG. 7C. Each layer 706, 708, 710, 712 may include the same material as the first layer 704. In some embodiments, the layers 706, 708, 710, 712 are graphene layers, which selectively form on the graphene layer of the first layer 704. The layers 704, 706, 708, 710, 712 may together form the first conductive layer 320. Although 5 layers are shown in FIG. 7D, the number of layers is not limited to 5. As described above, the first conductive layer 320 may include 3 to 6 2D material layers. As shown in FIG. 7D, a plasma process is performed to remove the blocking layer 702. The plasma process does not substantially affect the first conductive layer 320 or the conductive feature 412A. In some embodiments, the blocking layer 702 is removed after the formation of the first layer 704 but before the formation of the layers 706, 708, 710, 712. Subsequent processes such as the processes described in FIGS. 3E to 3H may be performed to fill the openings 701.

In some embodiments, there is a space between the first conductive layer 320 and the conductive feature 312A due to removing of the blocking layer 702. The second conductive layer 322 may fills the opening 701 and fills the space between the first conductive layer 320 and the conductive feature 312A.

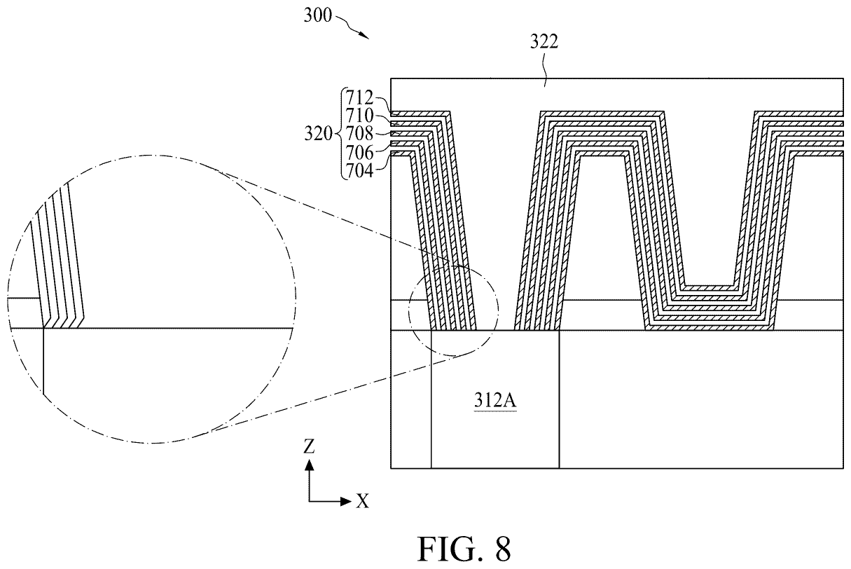

In some embodiments, as shown in FIG. 8, the blocking layer 702 is removed after forming the layer 704 and before forming the layers 706, 708, 710, 712. The bottoms of the layers 706, 708, 710, 712 may physically contact the underlying conductive feature 312A, while the bottom of the layer 704 may separate from the underlying conductive feature 312A.

FIGS. 6A to 6D and 7A to 7D illustrate various methods for selectively forming the first conductive layer 320 on the dielectric materials of the dielectric layer 316 and the etch stop layer 314. The first conductive layer 320 may be selectively formed on the dielectric materials of the dielectric layer 316 and the etch stop layer 314 by other suitable process.

The present disclosure in various embodiments provides an interconnect structure and methods of forming the same. In some embodiments, the interconnect structure includes a first conductive feature 326A disposed in a dielectric layer 316 and a second conductive feature 326S disposed in the dielectric layer 316. The first conductive feature 326A has a first width and includes a first conductive layer 320 and a second conductive layer 322. The second conductive feature 326S and a second width substantially greater than the first width and includes the first conductive layer 320, the second conductive layer 322, and a third conductive layer 324. Some embodiments may achieve advantages. For example, contact resistance and sheet resistance of the conductive features 326A, 326S are reduced.

An embodiment is an interconnect structure. The structure includes a first dielectric layer disposed over one or more devices, a first conductive feature disposed in the first dielectric layer, a second conductive feature disposed in the first dielectric layer, an etch stop layer disposed on the first dielectric layer, a second dielectric layer disposed on the etch stop layer, and a third conductive feature disposed in the second dielectric layer and the etch stop layer. The third conductive feature includes a first conductive layer, which includes a two-dimensional material. The structure further includes a fourth conductive feature disposed in the second dielectric layer and the etch stop layer. The third conductive feature and the fourth conductive feature include different number of layers.

Another embodiment is an interconnect structure. The structure includes a first dielectric layer disposed over one or more devices and a first conductive feature disposed in the first dielectric layer. The first conductive feature includes a first conductive layer in contact with the first dielectric layer and a second conductive layer filling a space between portions of the first conductive layer. The first conductive layer includes graphene or transition metal dichalcogenides. The structure further includes a second conductive feature disposed in the first dielectric layer. The second conductive feature includes the first conductive layer in contact with the first dielectric layer, the second conductive layer in contact with the first conductive layer, and a third conductive layer in contact with and surrounded by the second conductive layer.

A further embodiment is a method. The method includes forming a first dielectric layer over a second dielectric layer and forming first and second openings in the first dielectric layer. The first and second openings have different bottom critical dimensions. The method further includes forming a first conductive layer in the first and second openings, and the first conductive layer includes a two-dimensional material. The method further includes forming a second conductive layer, and the second conductive layer fills the first opening and is a conformal layer in the second opening. The method further includes forming a third conductive layer. The third conductive layer is formed over the first opening and fills the second opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An interconnect structure, comprising:
a first dielectric layer disposed over one or more devices;
a first conductive feature disposed in the first dielectric layer;
a second conductive feature disposed in the first dielectric layer;
an etch stop layer disposed on the first dielectric layer;
a second dielectric layer disposed on the etch stop layer;
a third conductive feature disposed in the second dielectric layer and the etch stop layer, wherein the third conductive feature comprises a first conductive layer, and the first conductive layer comprises a two-dimensional material; and
a fourth conductive feature disposed in the second dielectric layer and the etch stop layer, wherein the third conductive feature and the fourth conductive feature include different number of layers.

2. The interconnect structure of claim 1, wherein the third conductive feature consisting essentially of the first conductive layer and a second conductive layer.

3. The interconnect structure of claim 2, wherein the fourth conductive feature consisting essentially of the first conductive layer, the second conductive layer, and a third conductive layer.

4. The interconnect structure of claim 3, wherein the first conductive layer comprises graphene or transition metal dichalcogenides, the second conductive layer comprises Ru, Mo, Rh, or Ir, and the third conductive layer comprises Cu.

5. The interconnect structure of claim 1, wherein the third conductive feature has a first width, and the fourth conductive feature has a second width substantially greater than the first width.

6. The interconnect structure of claim 5, wherein the first width is less than about 10 nm, and the second width is greater than about 10 nm.

7. The interconnect structure of claim 6, wherein the second width ranges from about 20 nm to about 200 nm.

8. An interconnect structure, comprising:
a first dielectric layer disposed over one or more devices;
a first conductive feature disposed in the first dielectric layer, the first conductive feature comprising:
a first conductive layer interfacing the first dielectric layer, wherein the first conductive layer comprises graphene or transition metal dichalcogenides; and
a second conductive layer filling a space between portions of the first conductive layer; and
a second conductive feature disposed in the first dielectric layer, the second conductive feature comprising:
the first conductive layer interfacing the first dielectric layer;
the second conductive layer interfacing the first conductive layer; and
a third conductive layer interfacing and surrounded by the second conductive layer.

9. The interconnect structure of claim 8, wherein the first conductive layer comprises graphene, CrSe₂, CrTe₂, VS₂, VSe₂, VTe₂, TaS₂, TaSe₂, TaTe₂, MoS₂, MoSe₂, MoTe₂, NbS₂, NbSe₂, NbTe₂, WS₂, WSe₂, WTe₂, TiS₂, TiSe₂, TiTe₂, S, Se, Te, FeS, FeSe, BP, Mo₂C, Si, Ge, Sn, or combinations thereof, the second conductive layer comprises Ru, Mo, Rh, or Ir, and the third conductive layer comprises Cu.

10. The interconnect structure of claim 8, further comprising:
a second dielectric layer disposed below the first dielectric layer;
a third conductive feature disposed in the second dielectric layer; and
a fourth conductive feature disposed in the second dielectric layer.

11. The interconnect structure of claim 10, wherein the first conductive layer and the second conductive layer of the first conductive feature are in contact with the third conductive feature.

12. The interconnect structure of claim 10, wherein the first conductive layer of the first conductive feature is disposed between the second conductive layer and the third conductive feature.

13. The interconnect structure of claim 10, wherein the second conductive layer of the second conductive feature is disposed between the third conductive layer and the fourth conductive feature.

14. The interconnect structure of claim 8, wherein the second conductive layer of the second conductive feature is a conformal layer.

15. The interconnect structure of claim 8, wherein the first conductive feature has a first width, and the second conductive feature has a second width substantially greater than the first width.

16. An interconnect structure, comprising:
a first dielectric layer;
a first conductive feature disposed in the first dielectric layer;
a second dielectric layer disposed over the first dielectric layer; and
a third conductive feature disposed in the second dielectric layer, wherein the third conductive feature comprises a first two-dimensional material layer, a second two-dimensional material layer disposed on the first two-dimensional material layer, and a third two-dimensional material layer disposed on the second two-dimensional material layer, and a bottom of the first two-dimensional material layer is separated from the first conductive feature by the second two-dimensional material layer.

17. The interconnect structure of claim 16, wherein the first, second, and third two-dimensional material layers each comprises graphene, CrSe₂, CrTe₂, VS₂, VSe₂, VTe₂, TaS₂, TaSe₂, TaTe₂, MoS₂, MoSe₂, MoTe₂, NbS₂, NbSe₂, NbTe₂, WS₂, WSe₂, WTe₂, TiS₂, TiSe₂, TiTe₂, S, Se, Te, FeS, FeSe, BP, Mo₂C, Si, Ge, Sn, or combinations thereof.

18. The interconnect structure of claim 16, wherein the third conductive feature further comprises a conductive layer disposed over the third two-dimensional material layer.

19. The interconnect structure of claim 18, wherein the conductive layer comprises Ru, Mo, Rh, or Ir.

20. The interconnect structure of claim 16, further comprising an etch stop layer disposed between the first and second dielectric layers, wherein the third conductive feature is disposed in the etch stop layer.
